(19) United States
(12) Patent Application Publication
(10) Pub. No.: US 2012/0242356 A1
(43) Pub. Date: Sep. 27, 2012

(54) SPECIFIC CONTACT RESISTIVITY MEASUREMENT METHOD, SEMICONDUCTOR DEVICE FOR SPECIFIC CONTACT RESISTIVITY MEASUREMENT, AND METHOD FOR MANUFACTURING THE SAME

(75) Inventors: Kazuya Ohuchi, Somers, NY (US); Naoki Kusunoki, Wappingers Falls, NY (US)

(73) Assignee: TOSHIBA AMERICA ELECTRONIC COMPONENTS, INC., Irvine, CA (US)

(21) Appl. No.: 13/070,704

(22) Filed: Mar. 24, 2011

(51) Int. Cl. G01R 27/08; H01L 21/28; H01L 29/40

(52) U.S. Cl. 324/705; 257/48; 438/655; 257/E29.111; 257/E21.158

(57) ABSTRACT

A test structure, a method of employing the test structure, and a method of manufacturing the test structure are provided for measuring a contact resistance between a silicide and a semiconductor. The test structure includes a set of silicide layers separated from one another and upon which electrodes from a set of electrodes are placed. One pair of electrodes is employed to force a constant current through the silicide layers and a diffusion layer of a semiconductor substrate of the test structure. Another pair of electrodes determines a potential drop between the silicide layers and the diffusion layer. Based upon the constant current and the potential drop determined, a contact resistance is extracted.

### FIELD

Embodiments described herein relate generally to a method for measuring specific contact resistivity between a silicide layer and a semiconductor substrate, a semiconductor device for measuring specific contact resistivity, and a manufacturing method for fabricating the same.

### BACKGROUND

Silicon large-scale integrated circuits, among other device technologies, are increasing in use in order to provide support for the advanced information society of the future. An integrated circuit can be composed of a plurality of semiconductor devices, such as transistors or the like, which can be produced according to a variety of techniques. To continuously increase integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc. of resultant integrated circuits. However, as semiconductor devices and device features have become smaller, material selection becomes an increasingly important aspect and measurements of device characterizations become more central to fabricate reliable, high-speed, and small devices.

By way of example, silicides have been introduced to form ohmic and rectifying contacts to silicon. In conventional complimentary metal-oxide-silicon (CMOS) devices, a silicide can reduce sheet and contact resistances in contacts to gate, source, and/or drain regions of a MOS field effect transistor (MOSFET). As device scales continue to shrink, the silicide-semiconductor contract resistance contributes a significant part of a total resistance. Accordingly, accurate measurement of the silicide-semiconductor contact resistance enables manufacture of reliable, high-speed devices.

A commonly used test structure and method for contact resistance measurement is a four-terminal Kelvin test structure referred to as a cross-bridge Kelvin resistance (CBKR). In principle, the CBKR test structure enables specific contact resistance or contact resistivity to be measured and extracted without effects due to resistances of an underlying semiconductor or contacting metal, e.g., electrodes. However, CBKR test structures are sensitive to effects from parasitic currents, which reduce the accuracy of the measurements, especially when the specific contact resistance is less than 1×10⁻⁶ Ω·cm². As such, there is a minimum contact resistance which is measurable with the CBKR method. Accordingly, it would be desirable to accurately measure contact resistance, which are small, e.g., down to and beyond 1×10⁻⁹ Ω·cm², typical of emerging semiconductor device technology as well as future generations.

### BRIEF DESCRIPTION OF THE DRAWINGS

FIG. 1 is a cross-section view of a four-probe technique to measure contact resistance according to an embodiment of the subject innovation.

FIG. 2 is a top view of a four-probe technique to measure contact resistance according to an embodiment of the subject innovation.

FIG. 3 is a top view of a test structure to measure contact resistance according to an embodiment of the subject innovation.

FIG. 4 is a cross-section view of a test structure to measure contact resistance according to an embodiment of the subject innovation.

FIG. 5 is a cross-section view of a test structure to measure contact resistance according to an embodiment of the subject innovation.

FIG. 6 is an enlarged illustration of a silicide layer of the a test structure to measure contact resistance according to an embodiment of the subject innovation.

FIGS. 7 to 11 illustrate the steps of a process to form a test structure to measure a contact resistance between a silicide layer and a semiconductor substrate in accordance with various embodiments of the subject innovation.

FIG. 12 is a flow diagram of an example method for determining a contract resistance between a silicide layer and a semiconductor substrate in accordance with an embodiment of the subject innovation.

FIG. 13 is a flow diagram of an example method for manufacturing a test structure to measure a contact resistance between a silicide layer and a semiconductor substrate in accordance with various embodiments of the subject innovation.

FIG. 14 is a flow diagram of an example method for setting up measurement probes on a test structure to measure a contact resistance between a silicide layer and a semiconductor substrate in accordance with various embodiments of the subject innovation.

### DETAILED DESCRIPTION

The subject innovation provides a test structure, a method for manufacturing the test structure, and a method for employing the test structure. The test structure and measurement layout (e.g., probe position layout) facilitate an accurate measurement of contact resistance or specific contact resistance (contact resistivity) between a metal-semiconductor alloy layer on a semiconductor substrate. Contact resistance between the metal-semiconductor alloy layer, e.g., a silicide layer, and the semiconductor substrate, e.g., a silicon substrate, is a major contributor to overall resistance of source/drain resistance of a semiconductor device, which grows in significance when scaling semiconductor devices to smaller dimensions.

Moreover, as semiconductor device dimensions shrink, the magnitude of the contact resistance between the silicide layer and the silicon substrate decreases. Accordingly, accurate measurement of small contact resistances is desired to effectively design, characterize, and test semiconductor devices in current and future technology generations. Conventional measurement techniques lose accuracy at low contact resistances due to parasitic effects, current crowding, etc. With the subject innovation, high-precision measurements of contact resistance can be made at contact resistances as low as or below 1×10⁻⁹ Ω·cm².

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

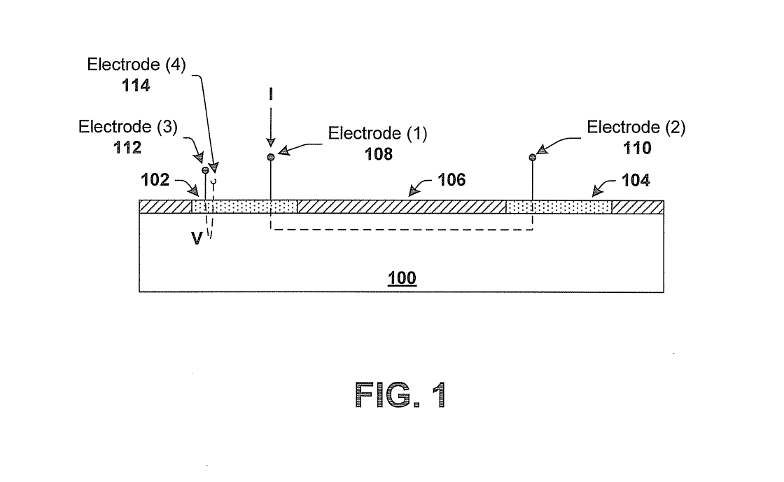

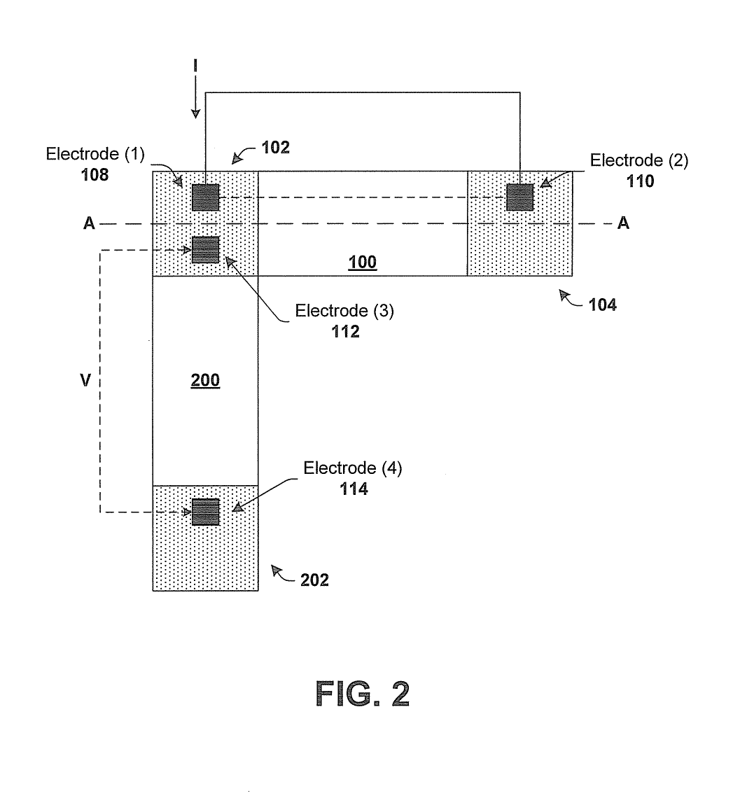

Referring first to FIGS. 1 and 2, a cross-section view (FIG. 1) and a top view (FIG. 2) of a four-probe techniques to measure contact resistance according to an embodiment of the subject innovation. FIGS. 1 and 2 will be described in conjunction and, as indicated in the figures, FIG. 1 is a cross-section view, along line A, of the structure depicted in FIG. 2.

In the cross-sectional view of FIG. 1, a substrate 100 is illustrated. Substrate 100 can be silicon or some other semiconductor material, e.g., germanium, etc. Substrate 100 can also include a region doped to form a diffusion layer. Formed thereon can be a set of silicide layers; particularly, silicide layer 102 and silicide layer 104. Separating silicide layer 102 and silicide layer 104 can be a silicide block layer 106 which can be an oxide or other insulating material. Silicide block layer 106 can reduce lateral current leaving the silicide layer 102 or silicide layer 104. Moreover, silicide block layer 106 can isolate silicide layers 102 and silicide layer 104 (or the contacts made thereto) from other contacts, metal, gate structures, etc. (not shown). Place on silicide layer 102 (a first silicide layer) is electrode 108 (electrode 1). Electrode 108 can be connected to a current source (not shown) to drive a current, I, through silicide layer 102, which conducts through silicide layer 102, across substrate 100, through silicide layer 104, and into electrode 110 (electrode 2) placed on silicide layer 104 and connected to the current source to complete a circuit.

Also placed on silicide layer 102 is an electrode 112 (electrode 3), as shown in FIGS. 1 and 2. Further, an electrode 114 (electrode 4) can be placed on a silicide layer 202 (a third silicide layer) shown in the top view illustrated in FIG. 2. As shown in FIG. 2, a substrate layer and/or a silicide block layer 200 can separate silicide layer 102 from silicide layer 202. It is to be appreciated that substrate 100 and substrate 200 can be a single slab of semiconductor material, e.g., silicon, on which a first silicide block layer, e.g., silicide block layer 106 shown in FIG. 1, and a second silicide block layer (not shown) can be respectively formed to separate silicide layer 102, silicide layer 104, and silicide layer 202 from one another.

Electrode 112 and electrode 114 can be coupled to a voltmeter configured to measure a voltage, V, between silicide layer 102 and silicide layer 202. Based upon the voltage V between electrode 112 and electrode 114 and the current driven between electrode 108 and electrode 110, a contact resistance between, for example, silicide layer 102 and substrate 100 can be determined. Moreover, a specific contact resistance or a contact resistivity can be extracted from the contact resistance.

In accordance with an aspect of the subject innovation, contact resistance is determined from the four-probe technique depicted in FIGS. 1 and 2 based upon the following principle. Current I is forced through electrode 108 to electrode 110 which results in at least three voltage drops between electrode 108 and electrode 110. For instance, a first voltage drop is due to a contact resistance between silicide 102 and substrate 100, a second voltage drop is due to a sheet resistance along substrate 100, and a third voltage drop is due to a contact resistance between substrate 100 and silicide layer 104. A high input impedance voltmeter, which measures the voltage between electrode 112 and electrode 114, passes very little current flow. Thus, a potential at electrode 114 is nearly identical to a potential in substrate 100 between silicide layer 102 on which electrode 112 is placed. Accordingly, the measured voltage between electrode 112 and electrode is only due to the contact resistance between silicide layer 102 and substrate 100, without effects from the sheet resistance or the contact resistance between substrate 100 and silicide layer 104. In other words, the contact resistance, R_{c}, between silicide layer 102 and substrate 100 can be determined according to the following:

$${R}_{c} = \frac{V}{I}$$

where V is the measured voltage between electrode 112 and electrode 114 and I is the current driven through electrode 108 to electrode 110. Once the contact resistance is determined, the specific contact resistance or contact resistivity, ρ_{c}, can be calculated according to the following expression:

ρ_{c}=R_{c}A_{c}

where A_{c} is the contact area such as, for example, the area of silicide layer 102 formed upon substrate 100.

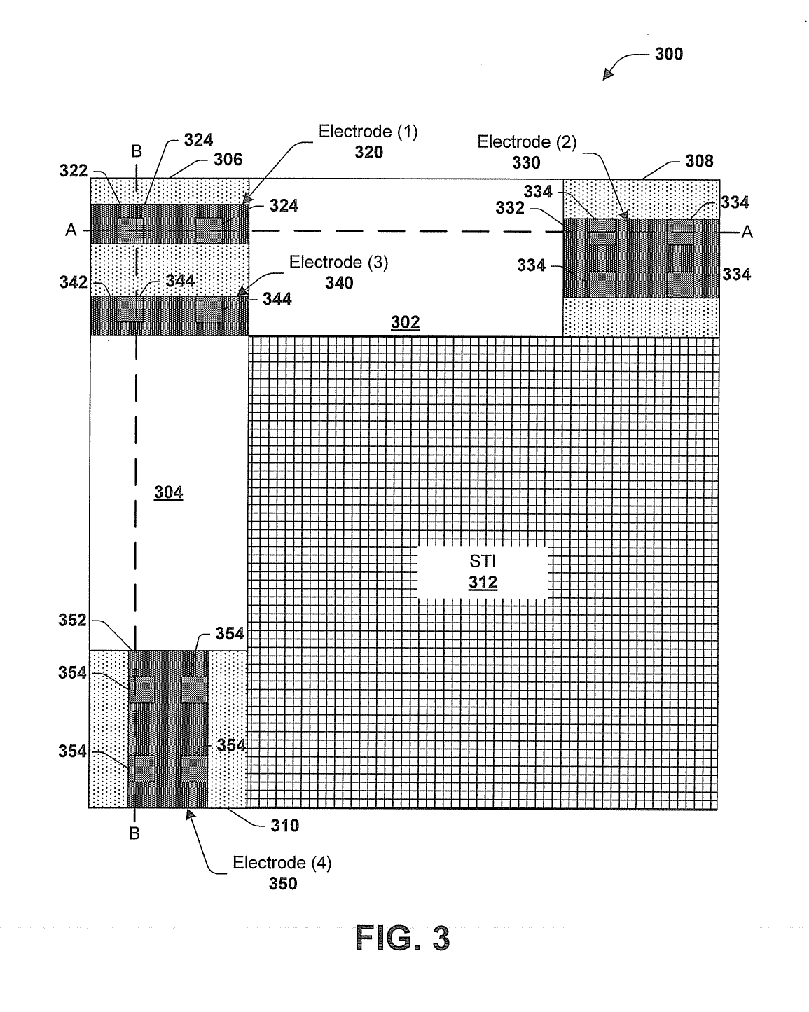

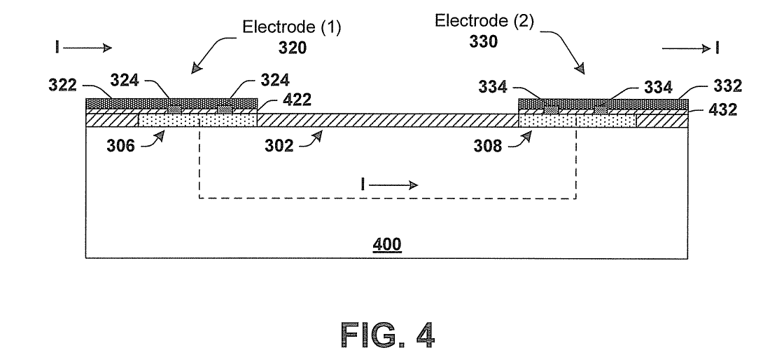

Turning to FIGS. 3 through 5, various views of a test structure 300 according to an embodiment are illustrated. Specifically, FIG. 3 depicts a top view of test structure 300, FIG. 4 is cross-section of test structure 300 along dashed line A shown in FIG. 3, and FIG. 4 is a cross-section of test structure 300 along dashed line B shown in FIG. 3.

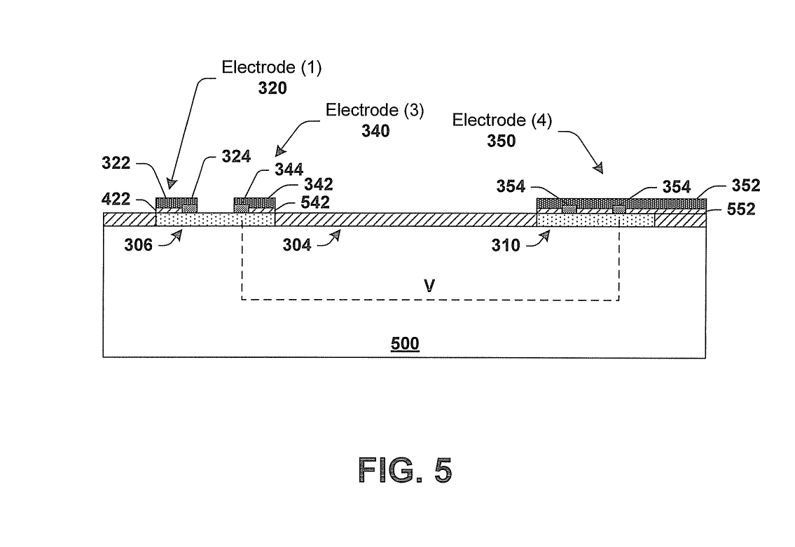

As shown in FIG. 3, test structure 300 includes a first silicide block layer 302 laid upon a diffusion layer of a silicon substrate (shown as substrate 400 or diffusion layer 400 in FIG. 400) and a second silicide block layer 304 upon the diffusion layer of the silicon substrate (illustrated as substrate 500 or diffusion layer 500 in FIG. 5). The first silicide block layer 302 isolates a first silicide layer 306, laid upon the silicon substrate, from a second silicide layer 308, also formed on the diffusion layer of the silicon substrate. Similarly, the second silicide block layer 304 separates the first silicide layer 306 from a third silicide layer 310. Silicide block layer 302 and silicide block layer 304 can be fabricated from an oxide material or other insulator. Test structure 300 can also include a shallow trench isolation (STI) feature 312, formed from an insulator, e.g., an oxide, configured to isolate semiconductor device features to prevent leakage currents. For instance, STI feature 312 can separate silicide layers 306, 308, and 310 from one another such that currents therebetween traverse through the silicon substrate beneath the silicide block layers 302 and 304, as intended.

Placed upon the first silicide layer 306 is an electrode 320 (first electrode or electrode 1), which comprises electrode contacts 324 and metal wiring 322. Metal wiring 322 enables connecting electrode 320 to a current source while electrode contacts 324 facilitate connection of electrode 320 to the first silicide layer 306. As shown in FIGS. 4 and 5, an insulation layer 422 can be located between metal wiring 322 and the first silicide layer 306 so that only electrode contacts 324 transfer current to the first silicide layer 306. However, in accordance with another embodiment, electrode 320 can connect to the first silicide layer 306 via metal wiring 322, wherein the insulation layer 422 and electrode contacts 324 are removed.

Test structure 300 further includes an electrode 330 (second electrode or electrode 2), which is similar in structure to electrode 320 (the first electrode). In particular, electrode 330 includes electrodes contacts 334 to facilitate connection to the second silicide layer 308 and metal wiring 332 to connect electrode contacts 334 to the current source. Further, metal wiring 332 can be insulated from the second silicide layer 308 by an insulation layer 432. However, similar to electrode 320 and in accordance with a further embodiment, electrode 330 can contact the second silicide layer 308 via metal wiring 332.

As described previously and shown in FIG. 4, a current, I, can be forced from electrode 320, through the first silicide layer 306, across the substrate 400, through the second silicide layer 308, and into electrode 330. While FIG. 3 depicts electrode 320 and electrode 330 having varying numbers of electrode contacts 324 and 334, respectively, it is to be appreciated that electrodes 320 and 330 can have different numbers of contacts, the same number of contacts, or no contacts as described herein.

Test structure 300 also includes an electrode 340 (third electrode or electrode 3), placed upon the first silicide layer 306, and comprises metal wiring 342, isolated from the first silicide layer 306 by an insulation layer 542, and electrode contacts 342. Electrode 340 can be coupled, via a high-impedance voltmeter, to electrode 350 (fourth electrode or electrode 4) placed upon the third silicide layer 310, which is separated from the first silicide layer 306 by second silicide block layer 304. Electrode 350 has a similar structure to the other electrodes and includes metal wiring 352, electrode contacts 354, and an insulation layer 552. The high-impedance voltmeter can measure a voltage, V, between electrode 340 and electrode 550 and shown in FIG. 5. As described above, current I and voltage V can be leverage to determine a contact resistance, R_{c}, between the first silicide layer 306 and the silicon substrate (substrate 400 and/or 500). In addition, from the contact resistance R_{c}, a specific contact resistance or contact resistivity ρ_{c}.

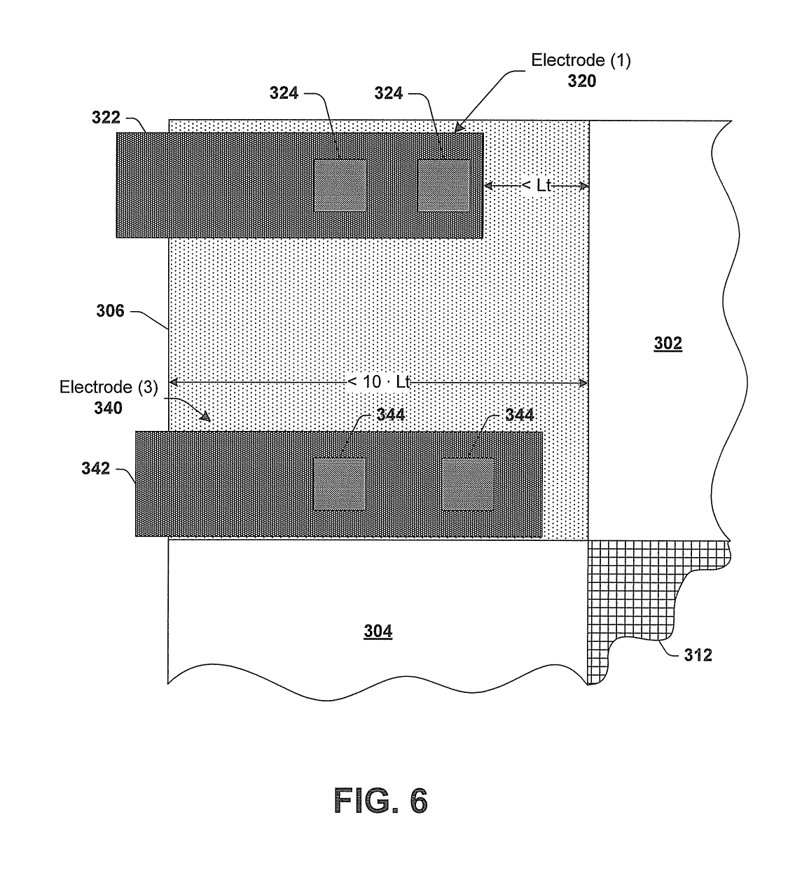

Turning to FIG. 6, an enlarged view of the first silicide layer 306 is illustrated. As shown in FIG. 6, according to an aspect, electrode 320, which is connected to the current source, is placed at a less than a transfer length (Lt) associated with the first silicide layer 306. The distance can be measured from an interface between the first silicide layer 306 and the first silicide block layer 302. Moreover, as shown in FIG. 6, in an embodiment, a width of the first silicide layer 306 of test structure 300, as measured from the interface with the first silicide block layer 302, does not exceed 10 times the transfer length (Lt).

Test structure 300 differs from conventional CBKR test structures in a number of respects. For instance, with conventional CBKR test structures, a pad or electrode employed to force a current is also employed as a silicide potential electrode or pad to measure a voltage. Accordingly, conventional CBKR test structures suffer from a drop in silicide potential due to the forced current. In contrast, test structure 300 has a silicide potential problem (electrode 340) which is separated from the force current wire (electrode 320). Moreover, in test structure 300, the silicide potential probe (electrode 340) is located close to a reference potential probe side of the first silicide layer 306 on which the force current wire is placed. For at least these reasons, test structure 300 can measure, accurately, contact resistance down to 1×10⁻⁹ Ω·cm², while conventional CBKR test structure show inaccuracy at contact resistances of 1×10⁻⁸ Ω·cm².

Another difference deals with a number of contacts. As shown in FIGS. 3 through 5, the electrodes include a plurality of contact areas. The plurality of contact areas enables averaging silicide potential caused by force current. Conventional CBKR test structures, however, suffer from silicide potential drops due to force current.

The test structures described above, e.g., test structure 300, is a simplified illustration to facilitate explanation of one or more embodiments. It is to be appreciated that test structure 300, when fabricated, can differ from the depictions described above. For instance, the materials that comprise the electrodes and layers of test structure 300 can vary and the respective placements of the electrodes and layers can also vary. Thus, it is to be appreciated that modifications to test structure 300 are comprehended provided that, with the test structure, a potential electrode is distinct from a force current electrode placed on the same silicided region and/or that the force current electrode is within a transfer length from a boundary with a silicide block layer.

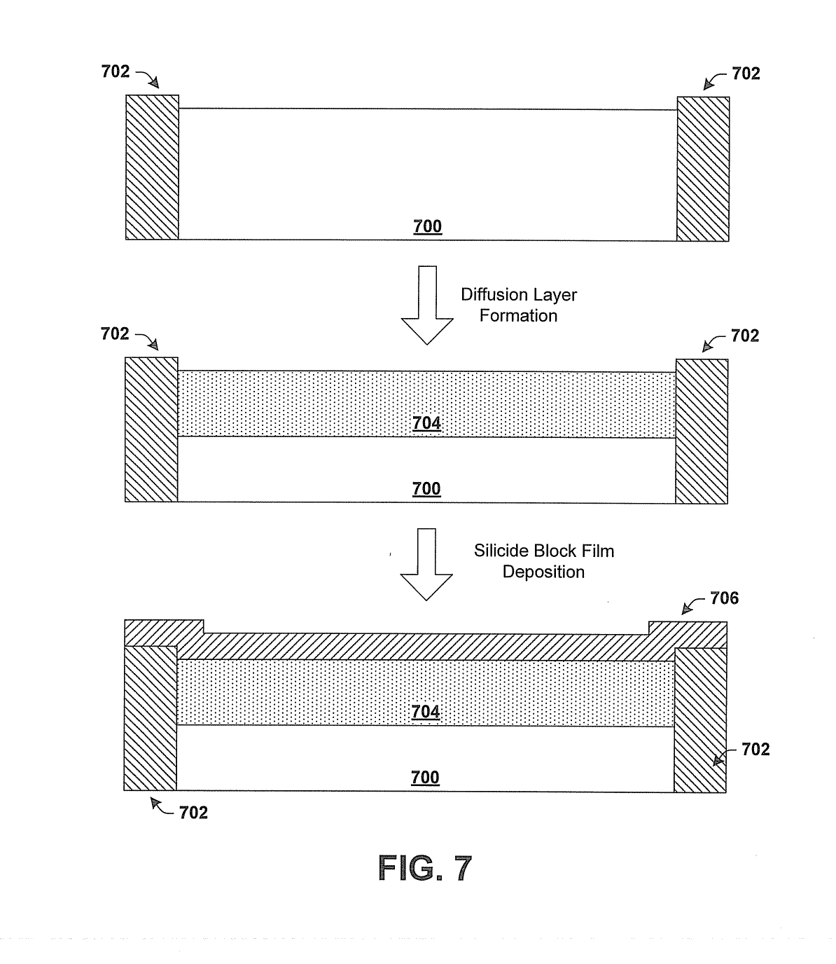

Turning next to FIGS. 7 to 11, various steps of a process to fabricate a test structure for measuring a contact resistance between a silicide layer and a diffusion layer in accordance with various embodiments of the subject innovation. It should be appreciated, however, that the test structure can be created using any suitable process or combination of processes and that the following description is provided by way of non-limiting example. Further, it should be appreciated that the processes presented in the following description can be utilized to fabricate any suitable product(s) and are not intended to be limited to the semiconductor devices, e.g., the test structures, described above.

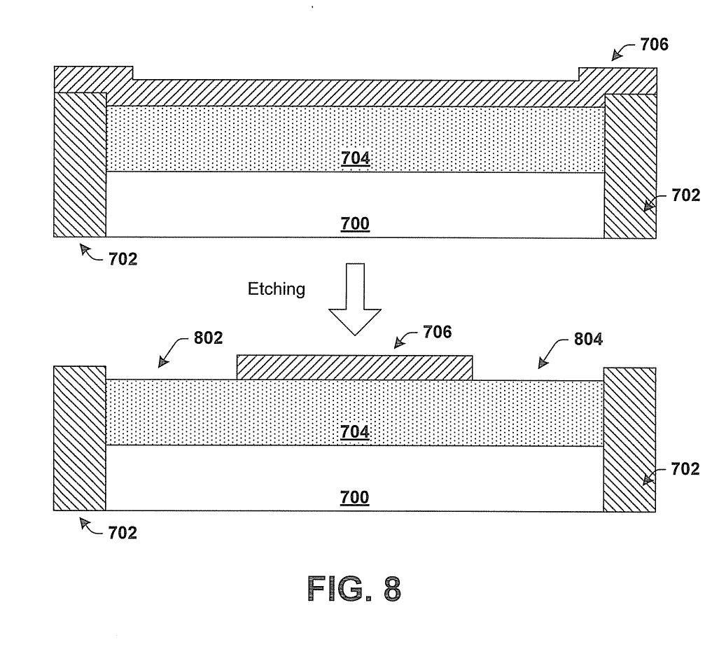

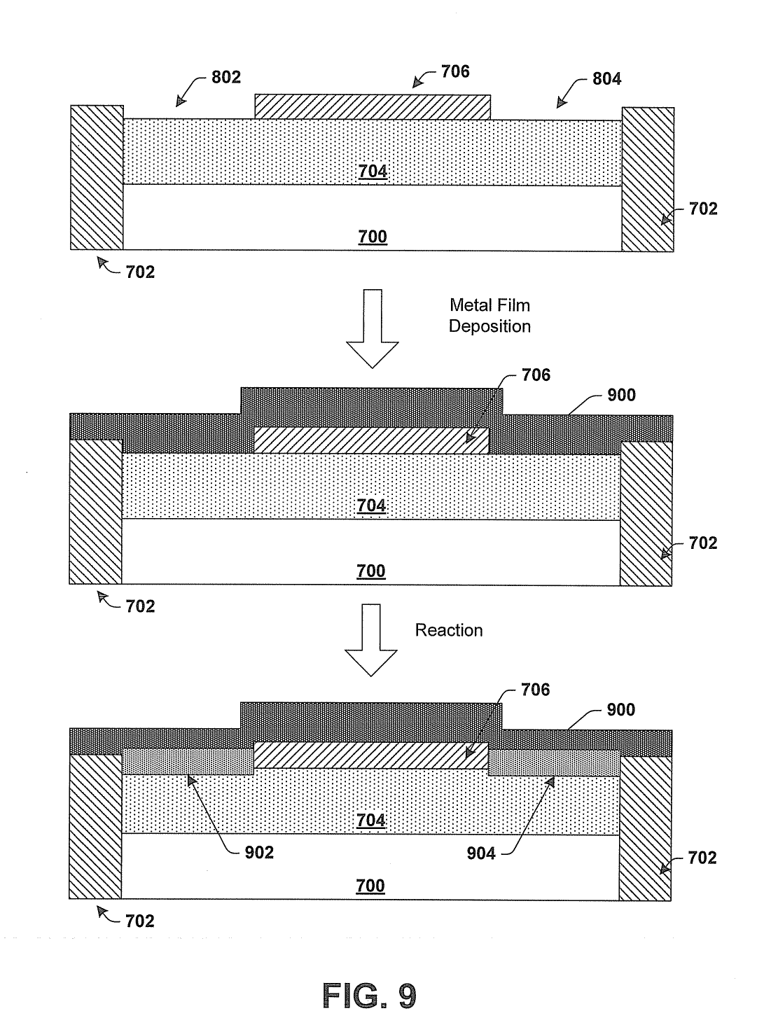

With reference first to FIG. 7, a first example step of test structure fabrication is accordance with an embodiment is illustrated. As FIG. 7 illustrates, test structure fabrication can start with a slab of semiconductor substrate 700, such as a silicon substrate, isolated by isolation features 702, e.g., shallow trench isolation features. Upon substrate 700, a diffusion layer 704 can be formed. In an example, diffusion layer 704 can be formed via doping, epitaxy, etc. Upon diffusion layer 704 a silicide block film 706 can be deposited. In an example, silicide block film 706 can be silicon nitride or a combination of silicon nitride and an oxide. FIG. 8 depicts an etching step wherein the silicide block film 706 is etched to form a first cavity 802 and a second cavity 804. In an example, a photo resist (not shown) can be deposited and patterned to enable etching of a pattern as shown in FIG. 8. As shown in FIG. 9, a metal film 900 can be deposited onto the wafer and fills the first cavity 802 and the second cavity 804. The metal film 900 can be nickel or an alloy. However, it is to be appreciated that other metals can be utilized. The metal film 900 can include a cap, e.g. titanium nitride (TiN). The wafer can be heated, via an annealing process, to trigger a metallurgical reaction between the deposited metal and the semiconductor in the diffusion layer 704. The metallurgical reaction creates a semiconductor-metal compound along the interface. Specifically, a first semiconductor-metal layer 902 and a second semiconductor-metal layer 904 are formed. In a specific, non-limiting example, the semiconductor of diffusion layer 704 can be silicon and the metal can be titanium, nickel, tungsten, etc. Accordingly, the first semiconductor-metal layer 902 and the second semiconductor-metal layer 904 can be silicide layers.

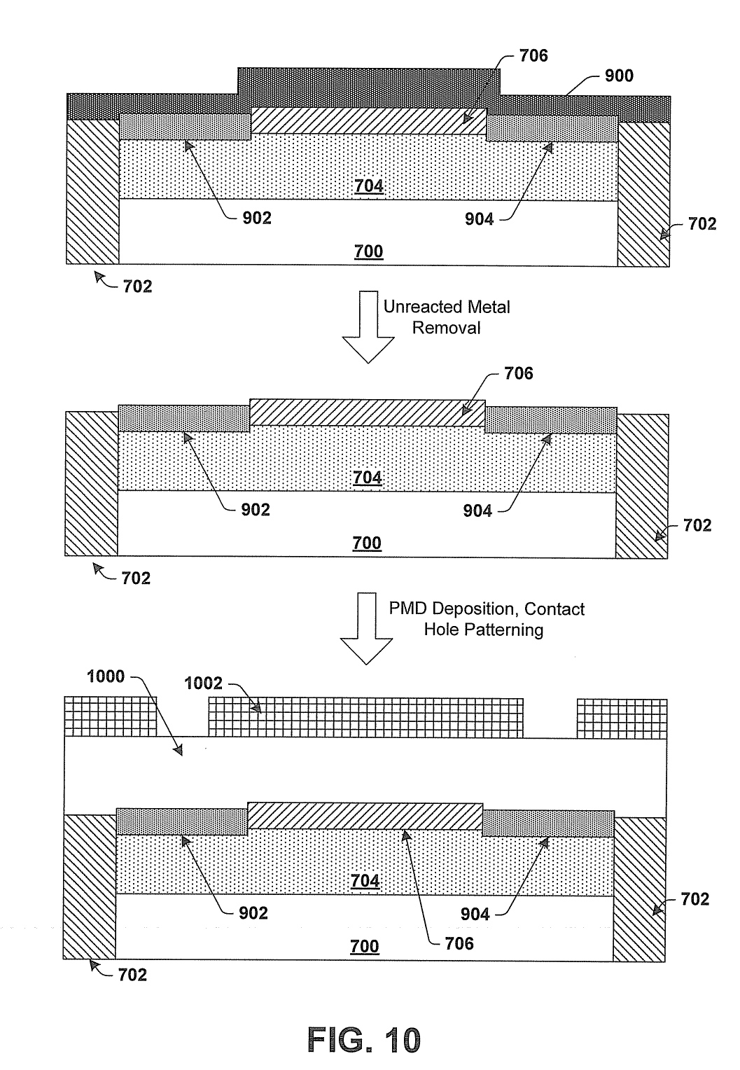

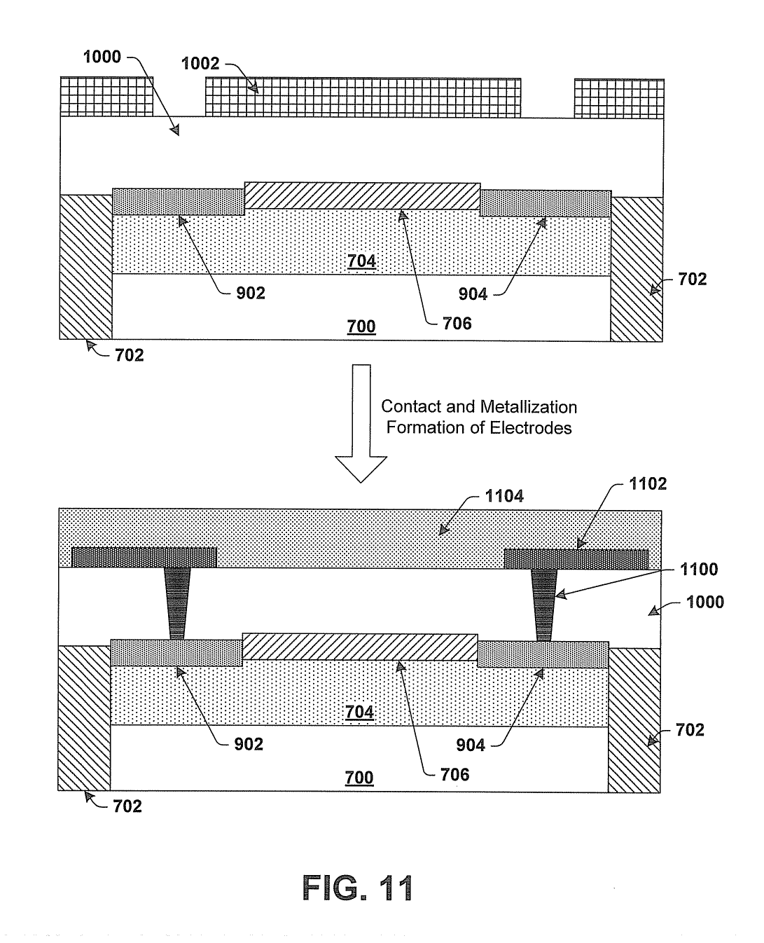

After the reaction reaches stability, excess portions of metal layer 900 can be removed and the wafer as shown in FIG. 10. To complete the test structure, electrodes as described previously, can be formed onto the silicide layers 902 and 904. To form the electrodes, a pre-metal dielectric material 1000 can deposited and subject to planarization. After planarization, contact holes can be patterned by depositing a photo resist 1002 to facilitate patterning by photolithography, for example. After photolithography, as shown in FIG. 11, portions of the pre-metal dielectric material 1000 can be etched to form contact holes filled with filled with a contact material such as tungsten (W) to form contacts 1100. Metallization layer 1102, e.g., copper, can be formed upon the pre-metal dielectric material 1000 and contacts 1100. An additional dielectric layer 1104 can be deposited to insulation the metallization layers 1102.

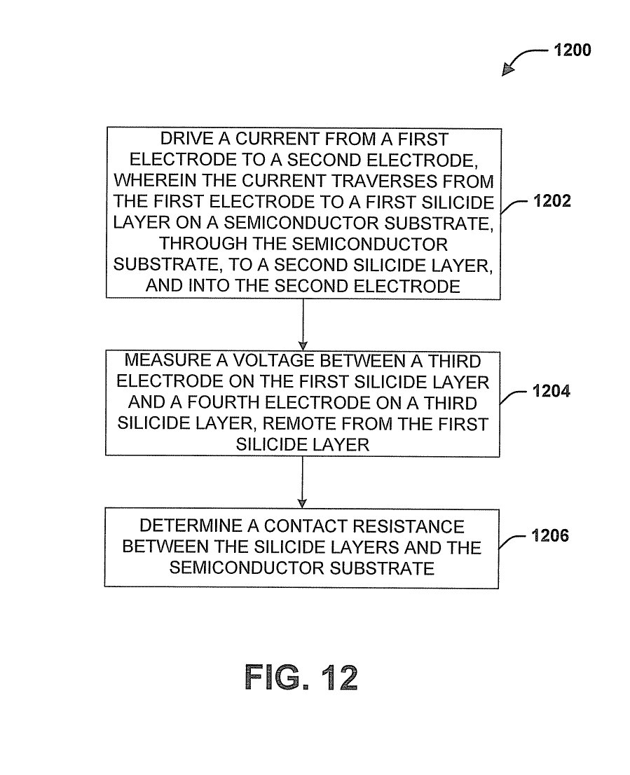

FIG. 12 is a flow diagram of an example method 1200 for determining a contract resistance between a silicide layer and a semiconductor substrate in accordance with an embodiment of the subject innovation. Method 1200 can begin at 1202 where a current is driven from a first electrode to a second electrode. According to an aspect, the current is forced such that it traverses from the first electrode into a first silicide layer on a semiconductor substrate, then through the semiconductor substrate to a second silicide layer remote from the first silicide layer, and then into the second electrode. At 1204, a voltage is measured between a third electrode on the first silicide layer and a fourth electrode on a third silicide layer remote from the first silicide layer and the second silicide layer. The voltage can be measured with a high impedance voltmeter that passes very little current. Thus, the voltage measure is essentially identical to a potential in the semiconductor substrate beneath the first silicide layer. At 1206, a contact resistance is determined between the silicide layers and the semiconductor substrate based up the current driven and the measured voltage. For instance, the contact resistance can be derived from the ratio of the measured voltage to the driven current.

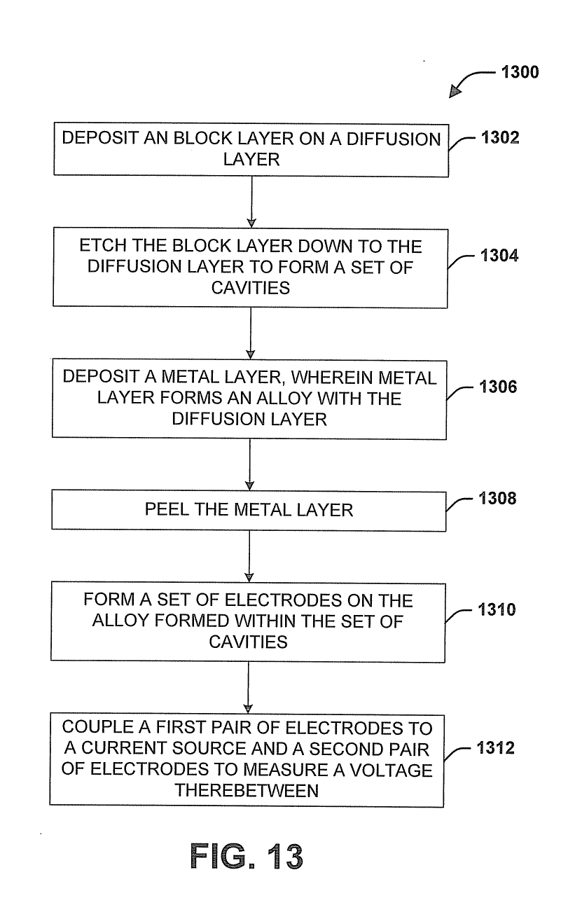

FIG. 13 is a flow diagram of an example method 1300 for manufacturing a test structure to measure a contact resistance between a silicide layer and a diffusion layer of a semiconductor substrate in accordance with various embodiments of the subject innovation. Method 1300 can commence at 1302 where a block layer is deposited on the diffusion layer. At 1304, the block layer is etched down to the diffusion layer to form a set of cavities. At 1306, a metal layer can be deposited, via sputter deposition, chemical vapor deposition, direct deposition, etc. The metal deposited fills the set of cavities and interacts with the diffusion layer to form an alloy, such as a silicide, with the semiconductor material. At 1308, the metal layer is peeled, leaving the silicide layers within the set of cavities. At 1310, a set of electrodes are formed on the silicide layers. At 1312, a first pair of electrodes is coupled to a current source to drive a current therebetween and a second pair of electrodes is coupled to a voltmeter to measure a voltage therebetween. In an aspect, the first pair of electrodes and the second pair of electrodes are disjoint pairs sharing no electrodes in common.

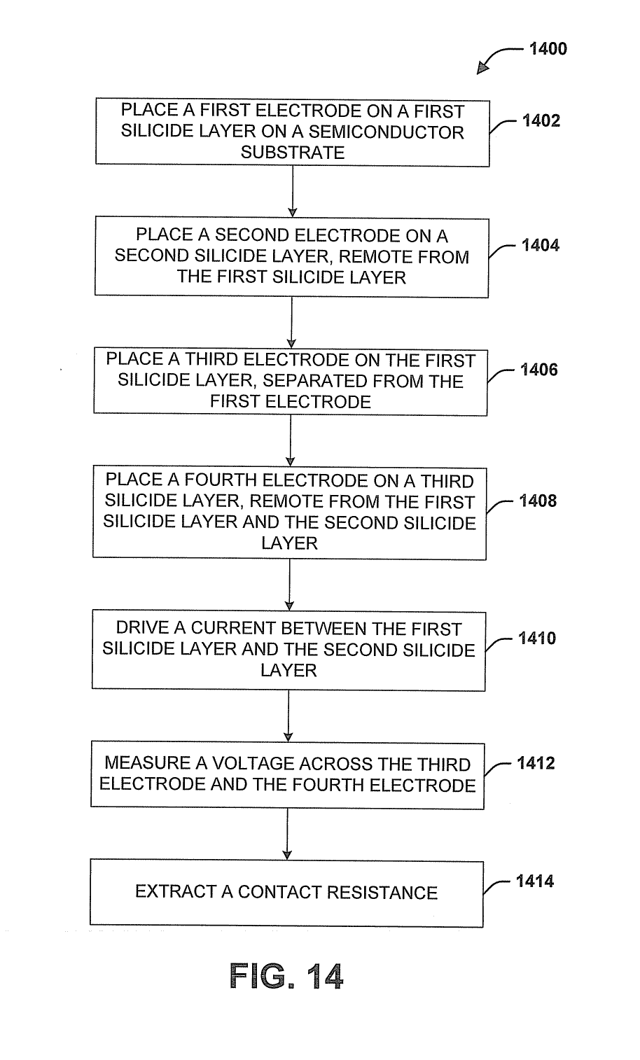

FIG. 14 is a flow diagram of an example method 1400 for setting up measurement probes on a test structure to measure a contact resistance between a silicide layer and a semiconductor substrate in accordance with various embodiments of the subject innovation. Method 1400 begins at 1402 where a first electrode is placed on a first silicide layer on a semiconductor substrate. At 1404, a second electrode, different from the first electrode, is placed on a second silicide layer on the semiconductor substrate. The second silicide layer is remote from the first silicide layer and separate therefrom by a first silicide block layer. At 1406, a third electrode, distinct from the first and second electrodes, is placed on the first silicide layer. The third electrode is placed so as not to contact the first electrode. At 1408, a fourth electrode is placed on a third silicide layer on the semiconductor substrate. In an embodiment, the fourth electrode is distinct from the first, second, and third electrodes. In addition, the third silicide layer is distinct from the first silicide layer and the second silicide layer. Moreover, the third silicide layer is separated from the first silicide layer and the second silicide layer by silicide block layers or shallow trench isolation features. At 1410, a current is driven between the first silicide layer and the second silicide layer, via the semiconductor substrate, by the first electrode and the second electrode. At 1412, a voltage between the third electrode and the fourth electrode is measured. The voltage can be measured by a high-impedance voltmeter such that the voltage measured matches a potential of the semiconductor substrate beneath the first silicide layer. At 1414, a contact resistance, a specific contact resistance of the silicide-semiconductor interface is extracted based upon the current driven and the voltage measured.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. A test device for measuring contact resistance, comprising:
a first silicide layer, a second silicide layer, and a third silicide layer on a diffusion layer, wherein the first silicide layer, the second silicide layer, and the third silicide layer are isolated from one another;
a first electrode connected to the first silicide layer;
a second electrode connected to the second silicide layer;
a third electrode connected to the first silicide layer; and
a fourth electrode connected to the third silicide layer,
wherein a constant current is forced from the first silicide layer to the second silicide layer via the first electrode and the second electrode and a potential difference is measured between the first silicide layer and the diffusion layer with the third electrode and the fourth electrode.

2. The test device of claim 1, wherein the first electrode and the third electrode are distinct and separate electrodes connected to the first silicide layer.

3. The test device of claim 2, wherein the third electrode is placed on the first silicide layer along a side closest to the third silicide layer on which the fourth electrode is connected.

4. The test device of claim 1, wherein the first electrode comprises a set of contact areas coupled together with metal wiring, wherein the set of contact areas physically contact the first silicide layer.

5. The test device of claim 4, wherein the metal wiring couples the set of contact areas to a current source that supplies the constant current.

6. The test device of claim 4, wherein contact areas in the set of contact areas of the first electrode are positioned a distance away from an interface between the first silicide layer and a first silicide block layer which operates to isolate the first silicide layer from the second silicide layer.

7. The test device of claim 6, wherein the distance is less than a transfer length associated with the first silicide layer.

8. The test device of claim 1, wherein the second electrode comprises a set of contact areas coupled together with metal wiring, wherein the set of contact areas physically contact the second silicide layer.

9. The test device of claim 8, wherein the metal wiring couples the set of contacts areas of the second electrode to a current source to complete a circuit with the first electrode.

10. The test device of claim 1, wherein the third electrode comprises a set of contact areas coupled together with metal wiring, wherein the set of contact areas physically contact the first silicide layer.

11. The test device of claim 10, wherein the metal wiring couples the set of contacts areas of the third electrode to a high-impedance voltmeter configured to measure a potential under the first silicide layer.

12. The test device of claim 1, wherein the fourth electrode comprises a set of contact areas coupled together with metal wiring, wherein the set of contact areas physically contact the third silicide layer.

13. The test device of claim 12, wherein the metal wiring couples the set of contacts areas of the fourth electrode to a high-impedance voltmeter also coupled to the third electrode on the first silicide layer.

14. The test device of claim 13, wherein the high-impedance voltmeter is configured to measure a potential difference between the third electrode and the fourth electrode, which matches the potential difference between the diffusion layer and the first silicide layer above the diffusion layer.

15. The test device of claim 1, wherein a width of the first silicide layer, the second silicide layer, or the third silicide layer is less than or equal to a multiple of ten of a transfer length associated with the first silicide layer, the second silicide layer, or the third silicide layer.

16. A method for measuring a contact resistance between a silicide layer and a semiconductor substrate, comprising:
driving a constant current through a first silicide layer, across a first diffusion layer of the semiconductor substrate, and through a second silicide layer, wherein driving the constant current is facilitated by a first electrode on the first silicide layer and a second electrode on the second silicide layer;
measuring a voltage drop between the first silicide layer and the diffusion layer by measuring a voltage between the first silicide layer and a third silicide layer separated by a second diffusion layer, wherein measuring the voltage drop is effectuated by a third electrode on the first silicide layer and a fourth electrode on the third silicide layer; and
determining a specific contact resistance between the first silicide layer and the diffusion layer based at least in part upon the constant current and the voltage drop measured.

17. The method of claim 16, wherein the determining the specific contact resistance further comprises:
identifying a contact resistance as a ratio of the voltage drop measured to the constant current; and
extracting the specific contact resistance as a product between the contact resistance an a contact area of the first electrode.

18. The method of claim 16, wherein the first electrode on the first silicide layer employed for driving the constant current is distinct from the third electrode on the first silicide layer employed for measuring the voltage drop.

19. A method for manufacturing a test device for measuring a contact resistance between a silicide and a semiconductor, comprising:
depositing an insulation layer on a diffusion layer of a semiconductor substrate;
etching portions of the insulation layer down to the diffusion layer to form a set of cavities;
depositing a metal layer into the set of cavities, wherein the metal layer reacts with semiconductor material of the diffusion layer to form a set of silicide layers respectively located within in the set of cavities;
removing excess metal of the metal layer;
forming a set of electrodes on the set of silicide layers; and
coupling a first pair of electrodes from the set of electrodes to a current source and a second pair of electrodes from the set of electrodes to a voltmeter, wherein the first pair of electrodes and the second pair of electrodes are disjoint pairs.

20. The method of claim 19, wherein the forming the set of electrodes on the set of silicide layers further comprises:
forming a first electrode on a first silicide layer of the set of silicide layers;
forming a second electrode on a second silicide layer of the set of silicide layers;
forming a third electrode on the first silicide layer of the set of silicide layers; and
forming a fourth electrode on a third silicide layer of the set of silicide layers,
wherein the first pair of electrodes includes the first electrode and the second electrode and the second pair of electrodes includes the third electrode and the fourth electrode.
